(19) United States
(12) Patent Application Publication
(10) Pub. No.: US 2021/0318612 A1
(43) Pub. Date: Oct. 14, 2021

(54) COMPOSITE DRY FILM RESIST FOR PHOTOLITHOGRAPHY

(71) Applicant: Intel Corporation, Santa Clara, CA (US)

(72) Inventors: Hongxia FENG, Chandler, AZ (US); Changhua LIU, Chandler, AZ (US); Bohan SHAN, Tempe, AZ (US); Dingying XU, Chandler, AZ (US); Leonel ARANA, Phoenix, AZ (US); Manuel GADOGBE, Chandler, AZ (US); Matthew TINGEY, Mesa, AZ (US); Julianne TROIANO, Scottsdale, AZ (US)

(21) Appl. No.: 17/356,536

(22) Filed: Jun. 24, 2021

(51) Int. Cl. G03F 7/038; G03F 7/20; G03F 7/32

(52) U.S. Cl. CPC G03F 7/038; G03F 7/32; G03F 7/2006

(57) ABSTRACT

The present disclosure is directed to a patterning process that includes providing a composite dry film resist on a surface, in which the composite dry film resist includes a base film, a barrier layer and a resist layer, in which the base film is disposed over the barrier layer and the barrier layer is disposed over the resist layer. In another aspect, the patterning process includes removing the base film from the barrier layer and exposing the barrier layer to form an exposure precursor, which has a first area and a second area, further exposing the first area of the exposure precursor to electromagnetic irradiation, which passes through the barrier layer and the resist layer in the exposed first area becomes water-insoluble, and removing the barrier layer and the unexposed second area to form a pattern template.

### BACKGROUND

Achieving a high patterning yield in a lithographic patterning process during semiconductor manufacturing has become increasingly important due to the larger package form factor, greater number of layers, and the smaller pitch size needed for server products. Among the two major failure modes that may occur during a lithographic patterning process are plating under resist (PUR) and full-plating defects. PUR refers to metal plating occurring at an undesired area, where the resist layer was partially missing from the substrate surface, caused, e.g., by a resist layer that is incompletely cured. The full-plating defect refers to metal plating occurring at an undesired area where the resist layer is completed delaminated from substrate surface. The above described defects are major yield loss factors that may need to be addressed.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 schematically shows a conventional composite dry film resist on a device;

FIG. 2 schematically shows a conventional photolithography process;

FIG. 3A schematically shows the presence of FM and a scratch on/in a conventional composite dry film resist;

FIG. 3B schematically shows the exposure of the conventional composite dry film resist including FM and a scratch on the base film;

FIG. 3C schematically shows the formation of defects in a conventional photolithography process caused by the FM and the scratch on the conventional composite dry film resist;

FIG. 4 schematically shows a composite dry film resist on a substrate in accordance with the present disclosure;

FIG. 5 schematically shows a photolithography process in accordance with the present disclosure;

FIG. 6A schematically shows the presence of FM and a scratch on/in a composite dry film resist in accordance with the present disclosure, and the removal of the base film;

FIG. 6B schematically shows the exposure of the composite dry film resist in accordance with the present disclosure without the base film and FM or the scratch on the base film;

FIG. 6C schematically shows that the formation of a defect-free device using the present photolithography process in accordance with the present disclosure; and

FIG. 7 shows a comparison of the defect density (the number of defects observed in the unit surface area, e.g. cm²) for a patterned product produced in accordance with the present disclosure with the defect density of a patterned product produced by a conventional photolithography process using a conventional composite dry film resist; measured by optical imaging and scanning the entire panel.

### DETAILED DESCRIPTION

Photolithography may refer to the process of exposing selected areas of a resist layer to electromagnetic irradiation (e.g., UV radiation). The process may be used in microfabrication to pattern parts of a composite dry film resist on a device. It uses electromagnetic irradiation to transfer a geometric pattern to a resist layer that includes a photosensitive material (e.g., dry film resist material).

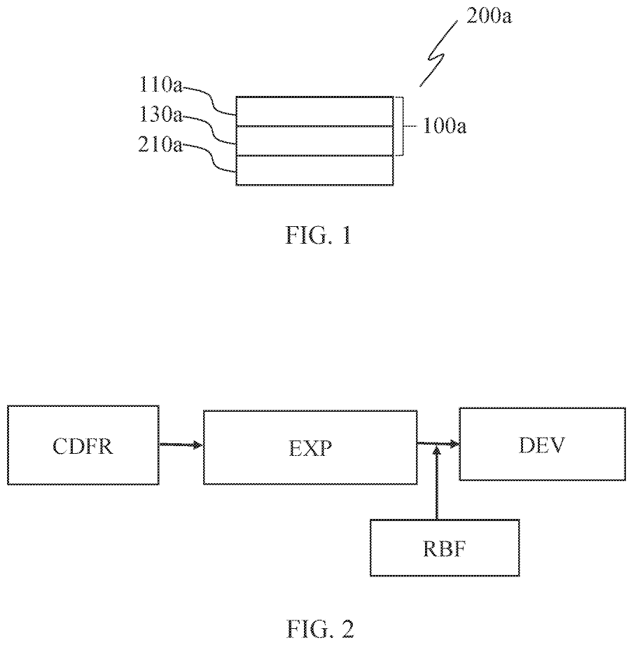

As shown in FIG. 1, a conventional composite dry film resist 100a on a device 200a typically includes a base film 110a (e.g., a polyethylene terephthalate (PET) film), which is disposed on a resist layer 130a, which itself is disposed on the surface of a substrate 210a. The conventional patterning process, as illustrated in FIG. 2, requires the removal of the base film 110a (RBF) from the composite dry film resist (CDFR) after irradiation exposure (EXP) and before development (DEV) due to the high tackiness of the unexposed resist. Therefore, the defects generated during all previous actions, e.g., lamination, handling, and foreign materials (FM) or lubricant particles on the base film 110a may be transferred onto the patterned intermediate or patterned product during irradiation exposure and may cause a negative impact on the lithographic patterning quality and the patterning yield.

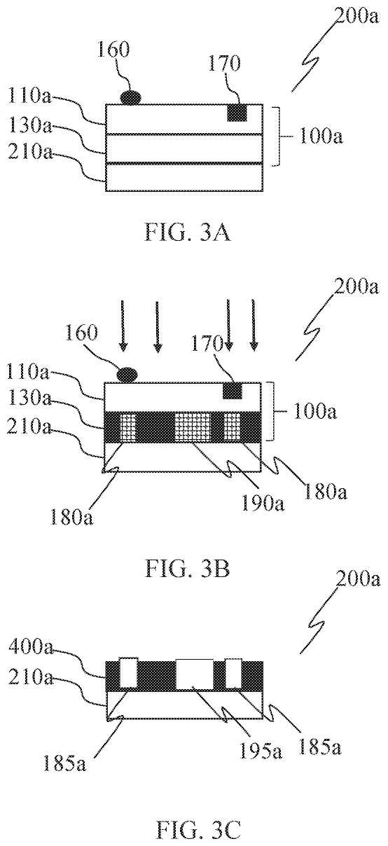

As illustrated in FIG. 3A to FIG. 3C, the conventional dry film resist laminated on a device 200a is shown in FIG. 3A, wherein an FM 160 may be disposed on the base film 110a, and a scratch 170 may be present in the base film 110a.

In FIG. 3B, the exposure precursor 300a may be exposed to electromagnetic irradiation (shown as downward arrows). However, at regions 180a covered by the FM 160 and the scratch 170, the electromagnetic irradiation does not reach the resist layer 130a at regions 180a, thereby preventing the resist layer 130a from being exposed to electromagnetic irradiation. The result shown in FIG. 3C indicates that, at regions 180a, there are defects 185a in the pattern template 400a, since the resist layer 130a was not irradiated and the resist material was not cured. These unintentional defects may be contrasted with an intentional absence of electromagnetic irradiation at region 190a, which caused the resist layer not to be irradiated due to patterning, and forming the intentional pattern 195a.

The approaches used to improve the patterning quality have included, for example, more frequent and intensive lithographic loop cleaning to remove FM. While this approach may decrease the possibility of FM on the panel, this approach may not be suitable for removing all defects from the base film. Another remedial measure includes a post-exposure baking process, which may increase the DFR bottom cure percentage, thereby decreasing the possibility of PUR defect. However, while post-exposure baking may increase the cure percentage of the resist layer due to low ultraviolet (UV) radiation dose caused by scattering, it cannot solve the full plating issue. Another approach is using an improved resist material with high UV penetration and an anti-static PET film. However, this approach also cannot solve the full plating issue.

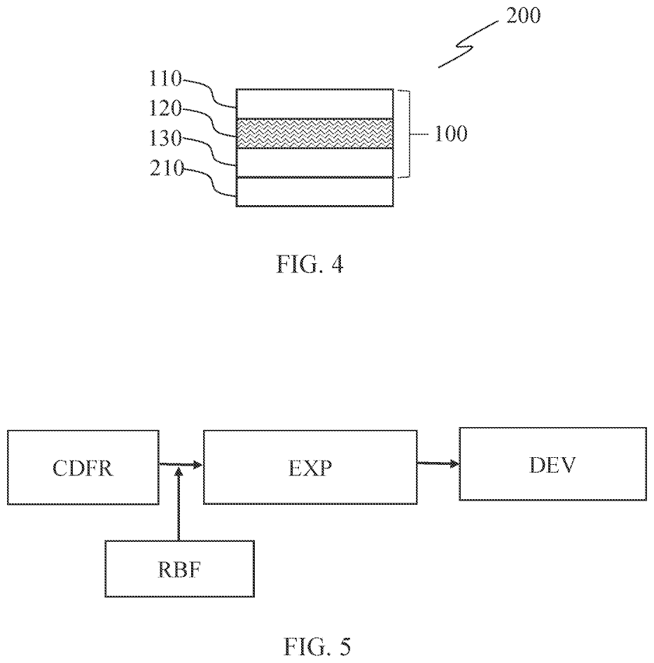

In a first aspect, there is disclosed a patterning process for ameliorating the issue stated above. The present patterning process may be used for making a patterned intermediate or a patterned product. The patterning process may include providing a composite dry film resist 100 on a surface of a device 200, as shown in FIG. 4. The device 200 includes a substrate 210, which may be a layer or segment or portion of the device 200. The composite dry film resist 100 may include a barrier layer 120, which may be made of a water-soluble polymer. As shown in FIG. 4, the barrier layer 120 may be disposed between a resist layer 130 and a base film 110.

In an aspect, the individual layers of the composite dry film resist 100 may be coated onto a substrate 210 or the dry film resist 100 may be pre-formed and laminated on the surface of the substrate 210, with the base film 110 being opposite of the substrate 210.

It should be understood that the term “substrate”, as used in this disclosure, may be representative of any material or layer of material that may be required to be patterned by a lithographic or photolithographic process.

In an aspect, after removing the base film 110 from the barrier layer 120 of the composite dry film resist 100, an exposure precursor 300 may be formed having an exposed barrier layer 120. By exposing only certain parts (e.g., areas) of the resist layer to the electromagnetic irradiation, those exposed areas (e.g., of the resist layer) may undergo a chemical reaction (e.g., polymerization) upon irradiation exposure. The chemical reaction may result in the material of the resist layer 130 becoming water-insoluble.

The exposure precursor 300 may generally have first areas and second areas, the first and the second areas defining a patterning for the substrate. A photolithographic process may include selectively exposing the first area of the exposure precursor 300 to electromagnetic irradiation, thereby allowing the resist layer in the exposed first area to become water-insoluble, while the resist layer in the second area remains water-soluble.

Accordingly, upon subsequent treatment with a water-based solvent (e.g., during development), the area may be exposed to the electromagnetic irradiation may remain on the substrate 210, while the unexposed material of the resist layer may be washed away. A layout pattern may be formed by the resist layer 130 that may be transferred to the substrate 210, resulting in a pattern template 400.

Subsequently, etching may be carried out, followed by a new material (e.g., in a deposition/plating) that may be disposed in the desired pattern upon the pattern template 400. Removal of the pattern template 400, made up substantially from the water-insoluble parts of the resist material (e.g., the reaction product of the irradiation exposure) may then give a patterned “product”.

With reference to FIG. 5, a composite dry film resist (CDFR) may be provided, for example, on a surface of a device. Advantageously, the patterning process according to the disclosure may include removing the base film from a barrier layer 120 (RBF) before exposing a dry film resist material (e.g., the first area of the exposure precursor) to electromagnetic irradiation (EXP) and development (DEV), and removal of barrier layer and unreacted resist material. This modification in the process, compared to the conventional process detailed in FIG. 2, is facilitated by the provision of a barrier layer 120, which may be a water-soluble polymer, between the resist layer 130 and the base film 110.

By removing the base film 110 from the barrier layer 120 and exposing the barrier layer 120 before exposing the dry film resist material to electromagnetic irradiation, any FM that may adhere to the base film or scratches or other imperfection in the base film 110 may be removed together with the base film 110. Those FM or scratches, if not removed, may result in patterning defects in the patterned product (as detailed in FIG. 3A to FIG. 3C). Hence, by removing the base film 110 from the barrier layer 120 and exposing the barrier layer before exposing the dry film resist material to electromagnetic irradiation, patterning defects in the patterned product may be decreased.

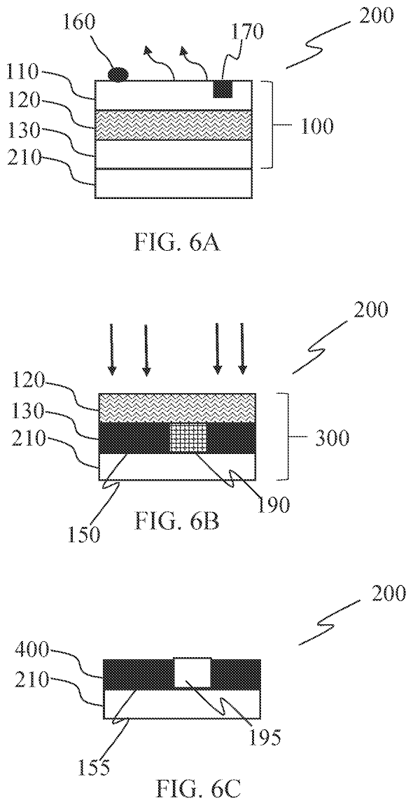

A photolithography process according to the present disclosure is shown in FIG. 6A to FIG. 6C. The dry film resist 100 may be laminated on a substrate 210 of a device 200 according to the disclosure is shown in FIG. 6A, wherein FM 160 may be disposed on a base film 110, and a scratch 170 may be present in the base film 110. The upward curvy arrows in FIG. 6A indicate the removal of the base film 110, thereby exposing barrier layer 120, which results in the formation of the exposure precursor 300 (FIG. 6B).

The exposure precursor 300 (in contrast to the exposure precursor 300a in FIG. 3B) does not contain any FM 160 or scratches 170, since these imperfections were removed together with the base film 110. Exposure with electromagnetic irradiation, as shown in FIG. 6B, irradiates evenly all of the areas of the resist layer 130 that are to be exposed. It is noted that at area 190 of the exposure precursor 300, there is no exposure to electromagnetic irradiation shown (due to the absence of downward arrows), which signifies an intentional pattern design. Since area 190 may not be exposed to electromagnetic irradiation, a differentiation into areas where electromagnetic irradiation may be present versus the areas where electromagnetic irradiation may be absent is achieved, i.e., the differentiation into a first area 150 and a second area 190 of the exposure precursor.

At the development stage, the barrier layer 120 may be removed together with any unexposed material of the resist layer 130, which leaves the pattern template 400 free of the water-insoluble material of the resist layer 130 that was exposed to the electromagnetic irradiation. As may be seen in FIG. 6C, the defects created by the FM 160 and the scratch 170 were not transferred to the pattern template 400. In contrast, the intended pattern design caused by the differentiation into a first area 150 and a second area 190 creating the pattern template 400, including an exposed resist material 155 and a void 195.

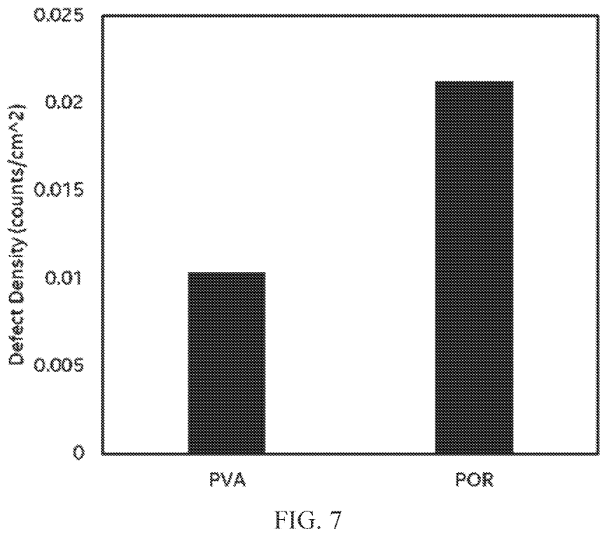

By using the patterning process according to the present disclosure, the patterning yield of the photolithography process may thereby be improved (see, FIG. 7). FIG. 7 shows the effectiveness of the patterning process in accordance with the present disclosure, as compared with a conventional patterning process. “PVA” represents values for the defect density that is obtained for a patterned product produced with the patterning process in accordance with the present disclosure, whereas “POR” indicates represents values for the defect density that is obtained for a patterned product produced with a conventional patterning process. It can be seen that the defect density for the patterned product produced with the patterning process in accordance with the present disclosure may be reduced to about one half as compared with the defect density for the patterned product produced with the conventional patterning process.

More advantageously, the barrier layer 120 may be made of a water-soluble polymer, which may facilitate removal of the barrier layer 120 after exposing the dry film resist material (e.g., the first area of the exposure precursor) to electromagnetic irradiation. Moreover, the material of the barrier layer may have a low tackiness, which may facilitate removal of the base film 110 before irradiation exposure to remove FM and/or scratches, and which may also avoid the barrier layer 120 from sticking to the process tool after the base film 110 is removed. More advantageously, the material of the barrier layer 120 may have a low oxygen permeability. In case a radical polymerization is utilized for the polymerization initiated by the irradiation exposure, such a low oxygen permeability may prevent oxygen from scavenging free radicals after irradiation exposure. Since the barrier layer 120 may include a water-soluble polymer, it may be removed together with the unexposed material of the resist layer 130 during development by dissolution in water or a water-based solvent and may have no further impact on downstream processes.

Accordingly, in some aspects of the disclosure, the water-soluble polymer for a barrier layer 120 may be selected from the group consisting of polyvinyl alcohol, polyacrylamide, polyacrylic acid, polyethylene glycol, polyamine, polyvinylpyrrolidone, a copolymer thereof and a combination thereof.

Additionally or alternatively, the substrate surface may undergo a pre-treatment before being laminated. For example, substrate surface 210 may be acid-cleaned before being laminated with the composite dry film resist 100.

As mentioned further above, the patterning process may involve that the base film 110 is removed from the barrier layer 120, which may expose the barrier layer 120 and result in the provision of an exposure precursor. The exposure precursor 300 may be the material that undergoes the irradiation exposure and may include, at least, the resist layer 130 and the barrier layer 120. The barrier layer 120, in this aspect of the present disclosure, may have the function of preventing oxygen from entering the resist layer 130, which may cause premature termination of the polymerization, e.g., due to scavenging of the radicals in a radical polymerization. It may also have the function of preventing scratches on the resist layer 130 and preventing the resist material from adhering to the tool.

For obtaining a pattern, the exposure precursor 300 may have a first area and a second area. The first area is the area designated for exposure, while the second area is the area that is designated to remain unexposed. In other words, the material of the resist layer 130 of the first area may react upon exposure and become water-insoluble, while the material of the resist layer 130 of the second area may remain unreacted and water-soluble and may be dissolved in water-based solvent together with the barrier layer 120 for removal or disposal thereof.

Distinguishing the first area from the second area may be carried out in at least two different modes, or a combination thereof: by using an optical mask and/or by using coherent electromagnetic irradiation (a laser).

When using an optical mask, the second area of the exposure area may be selectively blocked by the optical mask. Hence, only the first area gets exposed by electromagnetic irradiation. When using a laser, the precision of the laser may allow for only the first area to be exposed to electromagnetic irradiation.

Subsequent to the irradiation exposure, the material of the resist layer 130 may be distinguished into a water-insoluble first area and a water-soluble second area. Dissolution with water may remove the barrier layer 120 of the total area of the exposure precursor 300 and the water-soluble material of the second area. Thus, by using a water-soluble polymer included in the barrier layer 120, advantageously, the removal thereof may be carried out concurrently with the removal of the unexposed resist material. Removing all water-soluble material may form the pattern template 400, which includes the substrate 210 and the exposed (e.g., reacted) resist material. The exposed resist material may represent a pattern on the pattern template 400.

The patterning process may further include depositing a metal. The metal may include copper and/or tin. Upon depositing the metal, the patterning process may include removing the pattern template 400 to give a patterned product.

In an aspect of the disclosure, there is provided a composite dry film resist 100 for patterning processes. The composite dry film resist 100 may include at least 3 layers (i.e., the resist layer 130, the barrier layer 120 and the base film 110) as a pre-fabricated sheet or individually coated onto a surface. Each layer may have a first main side and a second main side, wherein the second main side is opposite to the first main side. The first main side and the second main side of each of the layers refer to the two largest surfaces of the layer. In particular, a layer typically extends into two directions (perpendicular to each other), while having a thickness in a direction that is perpendicular to the two directions in which the layer extends. The two surfaces that extend into the two directions are referred to herein as the first main side and a second main side. The distance between the two surfaces of the first main side and a second main side may refer to the thickness of each of the layers.

The layer structure according to the disclosure may be arranged in such a configuration that the first main side of the barrier layer 120 may be facing or be in contact with the base film 110, while the second main side of barrier layer 120 may be facing or be in contact with the resist layer 130.

The barrier layer 120 may have a thickness of between 1 μm and 10 μm, e.g., between 4 μm and 8 μm. At a thickness of the barrier layer 120 less than 1 μm, the oxygen blockage of the barrier layer 120 may be insufficient. At a thickness of the barrier layer 120 of more than 10 μm, the handling of the composite dry film resist 100 may be impeded.

According to some aspects of the present disclosure, the barrier layer 120 may be formed by being coated on the base film 110. Hence, the barrier layer 120 may be on a surface of the base film 110. The interaction between the barrier layer 120 and the base film 110 may be non-covalent. The association between the barrier layer 120 and the base film 110 may be an attractive interaction between the barrier layer 120 and the base film 110 that does not involve sharing of electrons, while resulting in adherence of the two materials. For example, such non-covalent interaction may include hydrophobic interaction, hydrophilic interaction, ionic interaction, hydrogen bonding, and/or van der Waals interaction. The adherence may be relatively weak. For example, the adherence may be so weak that removing the base film 110 from the barrier layer 120 to expose the barrier layer 120 leaves no, or substantially no, residues.

In an aspect of the disclosure, the base film 110 may include a material that may be a polymer. The material may provide sufficient flexibility for the film to be peeled off the barrier layer. The polymer may be a polyester. For example, the polyester may be PET.

The base film 110 may have a thickness of between 10 μm and 20 μm, e.g., between 14 μm and 18 μm. At a thickness below 10 μm, the base film 110 may become too soft and leach out. At a thickness above 20 μm, there may be handling issues. The first main side of the base film 110 may be substantially free of any material, while the second main side of the base film 110 may be facing or be in contact with the barrier layer 120.

During manufacture of the composite dry film resist 100, the base film 110 may be used as a base, on which the barrier layer 120 is coated. Subsequently, the resist layer 130 is coated on the barrier layer 120.

In an aspect of the disclosure, the resist layer 130 may include a resist material. The resist material may be a dry film resist material, a photo-imageable material, a solder resist material or a combination thereof. The resist material may undergo polymerization (e.g., radical polymerization) upon exposure to electromagnetic irradiation. The resist material may be water-soluble before irradiation exposure and water-insoluble after irradiation exposure. In other words, the resist material may be a monomeric substance that is water-soluble in its monomeric form and becomes water-insoluble upon reaction into the polymer. Accordingly, it is possible to dissolve unexposed (e.g., unreacted) resist material in water, while the exposed (e.g., reacted) resist material is retained on the surface.

The resist layer 130 may have a thickness of between 1 μm and 200 μm, e.g., between 5 μm and 100 μm, e.g., between 10 μm and 50 μm.

The layers may be stacked on each other such that the first main side of the resist layer 130 may be facing or be in contact with the barrier layer 120, while the second main side thereof may be facing or be in contact with the surface. The resist layer 130 may be formed by being coated on the barrier layer 120.

Before the composite dry film resist 100 is provided on a surface of a device 200, the patterning process may involve the lamination of the substrate 210. The lamination may involve providing the composite dry film resist 100 including an additional layer, which is a protective film (not shown). The protective film may be disposed on a second main side of the resist layer 130. Before lamination, the protective film may be peeled off, thereby exposing the resist layer 130, which may then be disposed on the substrate 210. The protective film may include a material that is a polymer, e.g., polyethylene.

Aspects of the disclosure and advantages described for the patterning process of the previous aspect can be analogously valid for the composite dry film resist of the second aspect, and vice versa. As the various features, material properties and advantages have already been described above and in the examples demonstrated herein, they shall not be iterated for brevity where possible.

In a first example, there is provided a patterning process comprising: providing a composite dry film resist on a surface, the composite dry film resist comprising a base film, a barrier layer and a resist layer, wherein the base film may be disposed over the barrier layer and the barrier layer may be disposed over the resist layer; removing the base film from the barrier layer and exposing the barrier layer to form an exposure precursor, wherein the exposure precursor has a first area and a second area; exposing the first area of the exposure precursor to electromagnetic irradiation, wherein the electromagnetic irradiation passes through the barrier layer and the resist layer in the exposed first area becomes water-insoluble; and removing the barrier layer and the unexposed second area to form a pattern template.

In a second example, the patterning process may further include acid-cleaning the surface before laminating the composite dry film resist thereon.

In a third example, removing the base film from the barrier layer includes removing any foreign matter and imperfections on the base film.

In a fourth example, exposing the first area of the exposure precursor to electromagnetic irradiation may include selectively masking the second area of the exposure precursor.

In a fifth example, the electromagnetic irradiation may include coherent electromagnetic irradiation.

In a sixth example, the patterning process may further include depositing a metal and removing the water-insoluble exposed material of the exposed first area.

In a seventh example, the patterning process may further include coating a water-soluble polymer on the base film to form the barrier layer.

In an eighth example, the water-soluble polymer may be selected from the group consisting of polyvinyl alcohol, polyacrylamide, polyacrylic acid, polyethylene glycol, polyamine, polyvinylpyrrolidone, and combinations and copolymers thereof.

In a ninth example, the barrier layer may be between 1 μm and 10 μm in thickness.

In a tenth example, the patterning process may further include coating a protective film on the resist layer, and removing the protective film prior to the lamination.

In an eleventh example, there is provided a composite dry film resist for patterning processes including: a base film; a barrier layer; a resist layer, and wherein the barrier layer may be disposed between the resist layer and the base film.

In a twelfth example, the barrier layer may include a water-soluble polymer.

In a thirteenth example, the water-soluble polymer may be selected from the group consisting of polyvinyl alcohol, polyacrylamide, polyacrylic acid, polyethylene glycol, polyamine, polyvinylpyrrolidone, and combinations and copolymers thereof.

In a fourteenth example, the base film may include a polyester.

In a fifteenth example, a thickness of the barrier layer may be between 1 μm and 10 μm.

In a sixteenth example, a thickness of the base film may be between 10 μm and 20 μm.

In a seventeenth example, a thickness of the resist layer may be between 1 μm and 200 μm.

In an eighteenth example, the resist layer may include a dry film resist material, a photo-imageable material, a solder resist material or a combination thereof.

In a nineteenth example, the composite dry film resist may further include a protective film coated on the resist layer opposite the barrier layer.

In a twentieth example, the protective film may include polyethylene.

In a twenty-first example, the substrate may include copper or tin, or a combination thereof.

The patterning process and the choice of materials presented above are intended to be exemplary for forming the patterned products. It will be apparent to those ordinary skilled practitioners that the foregoing process operations may be modified without departing from the spirit of the present disclosure.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

1. A patterning process comprising:
providing a composite dry film resist on a surface, the composite dry film resist comprising a base film, a barrier layer and a resist layer, wherein the base film is disposed over the barrier layer and the barrier layer is disposed over the resist layer;
removing the base film from the barrier layer and exposing the barrier layer to form an exposure precursor, wherein the exposure precursor has a first area and a second area;
exposing the first area of the exposure precursor to electromagnetic irradiation, wherein the electromagnetic irradiation passes through the barrier layer and the resist layer in the exposed first area becomes water-insoluble; and
removing the barrier layer and the unexposed second area to form a pattern template.

2. The patterning process of claim 1, further comprising acid-cleaning the surface before laminating the composite dry film resist thereon.

3. The patterning process of claim 1, wherein removing the base film from the barrier layer includes removing any foreign matter and imperfections on the base film.

4. The patterning process of claim 1, wherein exposing the first area of the exposure precursor to electromagnetic irradiation comprises selectively masking the second area of the exposure precursor.

5. The patterning process of claim 1, wherein the electromagnetic irradiation comprises coherent electromagnetic irradiation.

6. The patterning process of claim 1, further comprising depositing a metal and removing the water-insoluble exposed material of the exposed first area.

7. The patterning process of claim 2, further comprising coating a water-soluble polymer on the base film to form the barrier layer.

8. The patterning process of claim 7, wherein the water-soluble polymer is selected from the group consisting of polyvinyl alcohol, polyacrylamide, polyacrylic acid, polyethylene glycol, polyamine, polyvinylpyrrolidone, and combinations and copolymers thereof.

9. The patterning process of claim 7, wherein the barrier layer is between 1 μm and 10 μm in thickness.

10. The patterning process of claim 2, further comprises coating a protective film on the resist layer, and removing the protective film prior to the lamination.

11. A composite dry film resist for patterning processes comprising:
a base film;
a barrier layer; and
a resist layer, wherein the barrier layer is disposed between the resist layer and the base film.

12. The composite dry film resist of claim 11, wherein the barrier layer comprises a water-soluble polymer.

13. The composite dry film resist of claim 12, wherein the water-soluble polymer is selected from the group consisting of polyvinyl alcohol, polyacrylamide, polyacrylic acid, polyethylene glycol, polyamine, polyvinylpyrrolidone, and combinations and copolymers thereof.

14. The composite dry film resist of claim 11, wherein the base film comprises a polyester.

15. The composite dry film resist of claim 11, wherein a thickness of the barrier layer is between 1 μm and 10 μm.

16. The composite dry film resist of claim 11, wherein a thickness of the base film is between 10 μm and 20 μm.

17. The composite dry film resist of claim 11, wherein a thickness of the resist layer is between 1 μm and 200 μm.

18. The composite dry film resist of claim 11, wherein the resist layer comprises a dry film resist material, a photo-imageable material, a solder resist material or a combination thereof.

19. The composite dry film resist of claim 11, further comprising a protective film coated on the resist layer opposite the barrier layer.

20. The composite dry film resist of claim 19, wherein the protective film comprises polyethylene.
